(19) United States
(12) Patent Application Publication
(10) Pub. No.: US 2004/0207066 A1
(43) Pub. Date: Oct. 21, 2004

(54) LEAD ON CHIP PACKAGE AND LEADFRAME THEREOF

(76) Inventors: CHUNG-LIANG HSIAO, TAIPEI (TW); CHIH-KUNG HUANG, YI-LAN (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,583

(22) Filed: Apr. 21, 2003

(51) Int. Cl. H01L 23/48

(52) U.S. Cl. 257/690

(57) ABSTRACT

A lead on chip package comprises a chip, a leadframe, a nickel layer, a silver layer, an interfacial plating layer, and a tape. The chip comprises an active surface and bonding pads disposed on the active surface. The leadframe comprises leads and each lead comprises an inner lead and an outer lead, wherein the inner leads extend to the active surface of the chip. The nickel layer is plated onto the surface of the leadframe. The silver layer is plated onto the nickel layer on the inner lead. The interfacial plating layer improves the adhesion between the nickel and silver layers. The tape is adhered between the inner leads and the chip. Bonding wires electrically connect the silver layer on the inner leads and the bonding pads. Molding material encapsulates the chip and the inner leads and exposes the outer leads.

### BACKGROUND OF INVENTION

1. Field of the Invention

The present invention generally relates to a lead on chip package, and particularly to a high transmission lead on chip package.

2. Description of Related Art

In our modern communications-bursting world, integrated circuits (ICs) have become a part of life. No matter which aspect of life, we come across the finished product of an ICs. Rapid evolution and humanization of electronics technology have created a lot of feature-packed and complex electronic products which are lighter, smaller, shorter, and thinner in design for providing consumers with convenience and comfort. In semiconductor design, the line width of circuits has already reached 0.18 microns and is continuing to miniaturize as ULSI takes off. In terms of packaging, many different methods have been developed such as chip scale package (CSP), wafer level package, or multi-chip module (MCM), and the like. For assembly, there is also multi-level PCB for IC packages to be tightly arranged on the PCB. An IC leadframe provides a platform for electrically connecting the conductive lines to the PCB.

FIG. 1 shows the schematic diagram of a conventional lead on chip structure.

As illustrated in FIG. 1, the conventional lead on chip (LOC) package structure designed for reducing size is achieved by replacing the chip mount of the leadframe with the leads. The inner leads 110a of the leads 110 are inserted into the active surface 102 of the chip 100 and adhered to the chip 100 by a tape 108. The bonding pads 104 on the active surface 102 are electrically connected to the leads 110 by the bonding wires 106. A molding material 112 encapsulates the chip 100 and the inner leads 110a only exposing the outer leads 110b.

In the packaging of a memory device product, the development of 16M requires LOC made from NiFe leadframe for packaging. The LOC package structure can increase packaging density, so that a package with shorter signal paths and increased reliability is provided which can pass the JEDEC level 1 standard. Chasing the need for higher speed and capacity, the development of volatile memory (DRAM) has now reached SDRAM of over 100 MHz, and 133 MHz from EDO 66 MHz, and recently the introduction of the DDR format has even pushed the speed to above 200 MHz. Correspondingly, the requirement on the packaging of such devices has increased because the NiFe leadframe used in prior art has large resistance which cannot handle the increase in speed.

### SUMMARY OF INVENTION

It is an object of the present invention to provide a lead on chip (LOC hereinafter) structure by replacing the NiFe material of the substrate of the leadframe with copper or copper alloy to increase transmission speed. Furthermore a layer of nickel is plated above to prevent the copper from being adhered by the tape under high temperature.

It is another object of the present invention to provide an LOC package structure by replacing the NiFe material of the substrate of the leadframe with copper or copper alloy to increase transmission speed. The nickel layer effectively prevents the surface of the copper from oxidation under high temperature packaging process to ensure product quality.

It is another object of the present invention to provide an LOC package structure by replacing the NiFe material of the substrate of the leadframe with copper or copper alloy to increase transmission speed and plating a nickel layer above. Furthermore a silver layer is plated on the top surface at the end of the inner leads to increase the bondability between the inner leads and bonding wires.

It is another object of the present invention to provide an LOC package structure by replacing the NiFe material of the substrate of the leadframe with copper or copper alloy to increase transmission speed, plating a nickel layer above, and plating a silver layer on the top surface at the end of the inner leads. Furthermore a copper or silver layer can be deposited between the silver layer and the inner leads to improve the adherence between the nickel layer and the silver layer.

According to the above and other objects, the present invention provides an LOC package structure comprising a chip, a leadframe, a nickel layer, a silver layer, an interfacial plating layer, and a tape. The chip has an active surface and a plurality of bonding pads located on the active surface. The leadframe comprises a plurality of leads, wherein the leads further comprise inner leads and outer leads and the inner leads extend to the active surface of the chip. The nickel layer is plated on the leadframe and a silver layer is plated at the end of the inner leads on top of the nickel layer which is above the leadframe. The interfacial plating layer is used to increase the adhesion between the nickel layer and silver layer. The tape holds the chip and inner leads together and the bonding wires electrically connect the silver layer of the inner leads to the bonding pads.

According to the preferred embodiment of the present invention, an LOC package structure is provided on top of a second passivation layer. A nickel layer is plated on top of a conventional leadframe substrate using copper alloy to prevent the copper from peeling off by the tape under high temperature. In the high temperature process of packaging, the surface of the copper is prevented from oxidation to ensure product quality. The silver layer is plated at the end of the inner leads to increase bondability between the inner leads and bonding wires. Furthermore a layer of copper or silver is plated between the nickel layer and the silver layer to increase adhesion.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a sectional diagram of a conventional leads on chip package structure.

FIG. 2A is a sectional diagram of the leads on chip package structure according to a preferred embodiment of the present invention.

FIG. 2B is a sectional diagram of the leadframe of the present invention according to a preferred embodiment of the present invention.

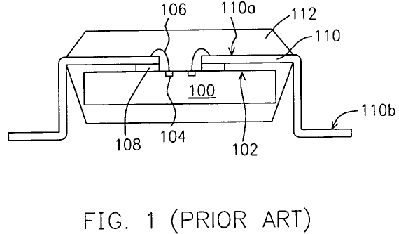

### DETAILED DESCRIPTION

Generally speaking, LOC products are usually reliable but the requirement on the specifications is comparatively high. This is especially so in the connection between the chip and leadframe because it is achieved by an insulating tape in which the specification of the tape is a crucial factor to the reliability of the LOC product. Furthermore, the tape is required to withstand a temperature of 400 degrees Celsius without solidifying or softening to provide stability under high temperature fabrication processes. Correspondingly, the bondability between the tape and leadframe is also an important aspect of the specification requirement and therefore a peeling test is performed to determine if the bondability of the tape can withstand a standard by placing the leadframe under temperatures between 200 to 300 degrees Celsius. The test is performed by heating the oven to 300 degrees Celsius for 30 minutes and heating the hot plate to 250 degrees Celsius for 15 minutes. The present invention replaces the NiFe alloy material of the substrate of the leadframe with copper or copper alloy for providing a good transmission rate and lower resistance, which meets the future demand of high speed transmission, and reliability of the tape to ensure product quality.

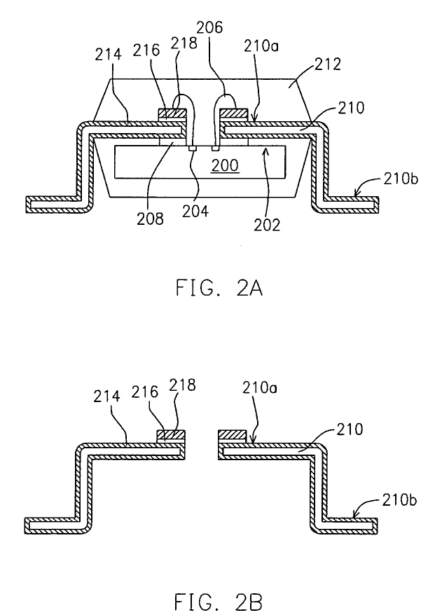

FIG. 2A shows a sectional view of the LOC package structure of the present invention.

Referring to FIG. 2A, a chip 200 comprises an active surface 202 and a plurality of bonding pads 204 are located on the active surface 202. The material of the substrate of the leadframe 201 is copper or copper alloy (Alloy 194, C7025, KCF125, EFTEC, or the like). The leadframe 201 comprises a plurality of leads 210, wherein each lead 210 further comprises an inner lead 210a and an outer lead 210b. The inner lead 210a extends to the active surface 202 of the chip 200.

FIG. 2B shows a sectional view of the leadframe of the present invention.

The LOC leadframe requires the consideration of at least the following factors: bondability, molding compound characteristics, solderability, and the bondability of the tape. The present invention uses plating of the surface of the leadframe to adjust these three factors.

Referring to FIG. 2B, the leadframe 201 goes through a series of plating processes such as cleaning, activation, etching, neutralization, and entire plating of all sides of the nickel layer 214 on the surface of the leadframe 201 to prevent corrosion and to provide good solderability, packaging and furthermore good bondability of the tape. A silver layer 218 is plated on the top surface of the nickel layer on the conductive layer at one end of the inner leads 201a. This can be performed by plating to provide good bondability. To improve the adhesion between the silver layer 218 and nickel 214, an interfacial layer 216 is added. The material of the interfacial layer 216 is selected between silver and a material belonging to the copper group and is strike plated between the nickel layer 214 and silver layer 218. Furthermore, Sn/Pb has good solderability so outer leads 210b do not require additional plating.

Simultaneously referring to FIGS. 2A and 2B, the tape 208 is adhered between inner leads 210a and chip 200, and during taping of the tape 208 and chip 200 the chip 200 and leads 210 are heated to a temperature between 200 and 300 degrees Celsius. The nickel layer 214 on top of the copper or copper alloy substrate of the leadframe 201 provides high temperature stability to prevent the peeling of tape 208 from the leadframe 201 and oxidation of the surface of the copper substrate to ensure product quality. The bonding wires 206 electrically connect the silver layer 219 on inner leads 210a, due to the end of the inner leads 210a having a silver layer 218, the bondability between leads 210 and bonding wires 201 is greatly increased. Molding material 212 encapsulates the chip 200 and inner leads 210a but exposes outer leads 210b. The nickel layer 214 plated on the surface of the leadframe 201 can prevent delamination between the molding material 212 and the leadframe 201 and provide good molding compound characteristics.

According to the above, the present invention provides the following advantages:

1. An LOC package structure, wherein the material of the leadframe is changed to copper alloy and a nickel layer is plated on top to prevent copper from peeling and delamination between the molding material and leadframe under high temperature.

2. An LOC package structure, wherein the material of the leadframe is changed to copper alloy and a nickel layer is plated on top to prevent oxidation of the copper surface and peeling of the tape to ensure product quality.

3. An LOC package structure, wherein the material of the leadframe is changed to copper alloy and a nickel layer is plated on top. A silver layer is plated on top of the inner leads to increase bondability between the inner leads and bonding wires.

4. An LOC package structure, wherein the material of the leadframe is changed to copper alloy and a nickel layer is plated on top. An interfacial layer of either silver or copper is plated between the inner leads and the silver layer to increase adherence between the nickel layer and the silver layer of the inner leads.

It will be apparent to those skilled in the art that various modifications and variations can be made to the structure and method of the present invention without departing from the scope or spirit of the present invention. In view of the foregoing description, it is intended that the present invention cover modifications and variations of this invention provided they fall within the scope of the following claims and their equivalents.

1. A lead on chip package structure comprising:
a leadframe having a substrate selected from a group including copper and a material from a copper alloy group, the leadframe comprising a plurality of leads, a nickel layer, a silver layer, and an interfacial layer, wherein each lead further comprises an inner lead and an outer lead, the nickel layer is plated on the surface of the conductive layer, the silver layer is deposited on the surface at an end of the leadframe, and the interfacial layer is deposited between the nickel layer and the silver layer;
a chip having an active surface where a plurality of bonding pads are located, and the inner leads of the leads are located on the active surface;
a tape adhered between the inner leads and the chip;
a molding material encapsulating the chip and the inner leads but exposing the outer lead.

2. The lead on chip package structure in claim 1, wherein the nickel layer, the interfacial plating layer, and the silver layer are formed by plating.

3. The lead on chip package structure in claim 1, the nickel layer is formed by plating all sides of the nickel layer.

4. The lead on chip package structure in claim 1, wherein the interfacial layer is formed by strike plating.

5. The lead on chip package structure in claim 1, wherein the silver layer is formed by spot plating.

6. The lead on chip package structure in claim 1, wherein the interfacial layer is selected from a group including silver and a material belonging to a copper group.

7. A leadframe of a lead on chip package structure comprising:
a leadframe having a substrate selected from a group including copper and a material belonging to a copper group, wherein the leadframe not comprising a chip pad but comprising a plurality of leads, a nickel layer, and an interfacial layer, wherein each lead further comprising an inner lead and an outer lead, the inner leads extend to an active surface of a chip, the nickel layer is located on the surface of the leadframe, the silver layer is located on the nickel layer at one end of the inner leads of the leadframe, and an interfacial plating layer is located between the nickel layer and the silver layer.

8. The lead on chip package structure in claim 7, wherein the nickel layer, the interfacial plating layer, and the silver layer are formed by plating.

9. The lead on chip package structure in claim 8, wherein the nickel layer is formed by plating all sides of the nickel layer.

10. The lead on chip package structure in claim 8, wherein the interfacial layer is formed by strike plating.

11. The lead on chip package structure in claim 8, wherein the silver layer is formed by spot plating.

12. The lead on chip package structure in claim 7, wherein the interfacial layer is selected from a group including silver and a material belonging to a copper group.
